(19) United States
(12) Patent Application Publication
(10) Pub. No.: US 2019/0229026 A1
(43) Pub. Date: Jul. 25, 2019

(54) Ceramic- based Fan - Out Wafer Level Packaging

(71) Applicants: Ananda H. Kumar, Fremont, CA (US); Srinivas Kumar, Fremont, CA (US); Tue Nguyen, Fremont, CA (US)

(72) Inventors: Ananda H. Kumar, Fremont, CA (US); Srinivas Kumar, Fremont, CA (US); Tue Nguyen, Fremont, CA (US)

(21) Appl. No.: 15/876,215

(22) Filed: Jan. 22, 2018

(51) Int. Cl. H01L 23/15; H01L 21/48; H01L 23/498; H01L 23/522; H01L 23/00; H01L 23/31; H05K 3/46; H01L 23/64

(52) U.S. Cl. CPC H01L 23/15; H05K 2201/068; H01L 23/49822; H01L 23/5226; H01L 24/14; H01L 23/3128; H01L 23/49816; H01L 24/08; H01L 21/486; H01L 21/4867; H05K 3/4629; H01L 23/64; H01L 2224/04105; H01L 2224/0231; H01L 2224/32225; H01L 2924/15311; H01L 2224/05008; H01L 21/4807

(57) ABSTRACT

Ceramic boards with thermal expansion similar to that of silicon can be used to support semiconductor chips in a fan out wafer level packaging process. The ceramic board can include sintered ceramic sheets with embedded vias and interconnect lines, together with passive components such as resistors, capacitors and inductors.

### BACKGROUND

Microelectronic components are becoming smaller due advance in semiconductor manufacturing technology, However, the contact size of the semiconductor chips, e.g., the bond pads and the bond pad pitches of the semiconductor chips, cannot be reduced as readily, at least due to the limitation of bonding technology. Thus bond pad fan out processes, such as wire bonding, can be used to spread the contact pads of the semiconductor chips over a larger area.

Recently, fan-out wafer-level packaging (FOWLP) is a packaging process in which contacts of a semiconductor die are redistributed over a larger area through a redistribution layer (RDL). After the semiconductor chips are formed, they are diced, and redistributed on a carrier with a larger separation between them. A redistribution layer can be formed on the surface of the distributed semiconductor chips. The redistribution layer can include metal and dielectric layers, which can reroute the IO of the semiconductor chips to a larger pitch. The metal layer include interconnects connecting the bond pads of the semiconductor chips to corresponded terminal pads having larger separation. The dielectric layer serves to isolate the interconnects.

FIGS. 1A(a)-1A(f) and 1B(a)-1B(e) illustrate a prior art fan out wafer level packaging process according to some embodiments. FIGS. 1A(a)-1A(f) show a process of fan out wafer level packaging. After the semiconductor chips are fabricated on a wafer, the individual semiconductor chips 110 are diced, and tested. The good semiconductor chips are then assembled on a sacrificial layer 111 on a carrier 112, with the active side, e.g., the surface of the semiconductor chips that contains the bond pads for interconnection, facing down. The carrier 112 can be a wafer tape that can be used in the dicing process. The carrier can be a releasable substrate material or a wafer with an adhesive layer. The sacrificial layer can be a dielectric layer or a passivation layer, having an organic material such as polyimide or an inorganic material such as silicon oxide or silicon nitride. The semiconductor chips 110 are spread out, e.g., separating from each other at a pitch that allows a larger separation of the terminal pads that are corresponded to the bond pads (FIG. 1A(a)).

A molded layer 120 can be applied on the semiconductor chips 110, encapsulating the semiconductor chips 110 (FIG. 1A(b)). The molded layer can include a polymer material, such as epoxy resin. The encapsulated semiconductor chips 110 are then removed from the carrier, for example, by removing the sacrificial layer. The sacrificial layer can be cleaned, for example, to expose the active surfaces and the bond pads of the semiconductor chips 110 (FIG. 1A(c)).

A redistribution layer 130 is fabricated on the encapsulated semiconductor chips. The redistribution layer 130 can include one or more layers of dielectric 131, and multiple interconnect lines and vias 132 that connect the bond pads of the semiconductor chips 110 to external terminal pads of the redistribution layer. The dielectric layer 131 can include an organic material such as polyimide or an inorganic material such as silicon oxide or silicon nitride. The dielectric layer 131 can provide a planar surface that is substantially flush with a surface of the molding layer surrounding the semiconductor chips.

The interconnect lines and vias can include a metal, such as aluminum, copper, tungsten, titanium, titanium nitride. For example, vias can be disposed directly on the bond pads, and in the dielectric portion between the interconnect lines.

The terminal pads are configured to have a larger pitch than that of the bond pads, e.g., the terminal pads can have a larger separation between each other, to ease the connection of the semiconductor chips 110 to another device, such as to an assembling board (FIG. 1A(d)).

The terminal pads are disposed on an external surface of the redistribution layer, e.g., on a surface that exposed to the ambient. The devices, e.g., the semiconductor chips connected to the terminal pads, can be tested to identify good devices. The terminal pads can be connected to terminal pads of other devices, for example, by a flip chip process. Solder balls 140 can be formed on the terminal pads. The wafer can be diced to individual devices (FIG. 1A(e)), which include a semiconductor chips with fan out terminal pads (FIG. 1A(f)).

FIGS. 1B(a)-1B(f) show a process for forming a redistribution layer, for example, for the FIGS. 1A(d) and 1A(e). The redistribution layer can include one or more interconnect lines embedded between one or more dielectric layers. FIG. 1B(a) shows the ceramic board 120 having the semiconductor chip 110 placed therein. The semiconductor chip 110 can have bond pads 113 forming on an external surface of the semiconductor chip 110, for connecting the devices inside the semiconductor chip 110 with the outside elements. Not shown in the semiconductor chip 110 are the devices inside the semiconductor chip 110 that have the bond pads 113 as the external contacts.

FIG. 1B(b) shows a passivation layer 131A, e.g., a dielectric layer from the one or more dielectric layers 131, formed on the surface of the semiconductor chip with openings to expose the surfaces of the bond pads. For example, a blanket dielectric layer can be deposited on the ceramic and chip surfaces. Patterning can be formed to remove the portions of the dielectric layer on the bond pad surfaces.

Interconnect lines 132A, e.g., some interconnect lines from the one or more interconnect lines 132, can be formed on the exposed surface of the bond pads. Typically, one interconnect line connects to one bond pad surface. In some cases, if two bond pads are to be connected to each other, one interconnect line can be used to couple to both bond pad surfaces. In some cases, if there is no connection for a bond pad, e.g., the bond pad is float with no connectivity, no interconnect line is needed for the bond pad.

FIG. 1B(c) shows a passivation layer 131B, e.g., another dielectric layer from the one or more dielectric layers 131, formed on the surface of the interconnect lines 132A and on portions of the dielectric layer 131A, together with openings to expose portions of the interconnect lines 132A. For example, a blanket dielectric layer can be deposited. Patterning can be formed to remove the portions of the dielectric layer on the portions of the interconnect lines 132A that needed to be exposed.

FIG. 1B(d) shows metal lines 132B disposed on the exposed portions of the interconnect lines 132A. The metal lines 132B can serve as the underlayer for coupling the solder bumps 140 (FIG. 1B(e)). Alternatively, wire bonds can be attached to the metal lines 132B.

Since the interconnect lines are disposed above the semiconductor chips and above the molding layer, thermal expansion mismatch between silicon (the substrate material of the semiconductor chips) and the polymer material forming the molding layer can affect the reliability of the packaging process.

### SUMMARY

In some embodiments, the present invention discloses a ceramic based fan out wafer level packaging process, and packages formed by the ceramic based fan out wafer level packaging process. The ceramic based fan out wafer level packaging process can include a ceramic board in which semiconductor chips can be placed therein. The ceramic board can form a frame surrounding the semiconductor chips. The ceramic board can have thermal expansion matches with silicon, thus can allow the fabrication of fan out interconnect lines running between the semiconductor chips and the ceramic board.

Fan out interconnects can be prefabricated in the ceramic board, together with other features such as embedded passive components. Terminal pads or via extenders can be used for connection with the semiconductor chips or with other elements.

Fan out interconnects can be fabricated in a redistribution layer disposed on the ceramic board. The redistribution layer can include terminal pads for connection with the semiconductor chips and with other elements. The redistribution layer can include interconnect lines to connect the bonding pads of the semiconductor chips with the terminal pads of the redistribution layer. The redistribution layer can include interconnect lines, wire bonding, or sheet interconnect to connect the bonding pads of the semiconductor chips with the interconnect lines in the ceramic board.

### BRIEF DESCRIPTION OF THE DRAWINGS

FIGS. 1A(a)-1A(f) and 1B(a)-1B(e) illustrate a prior art fan out wafer level packaging process according to some embodiments.

FIGS. 2A-2C illustrate configurations for ceramic boards according to some embodiments.

FIGS. 3A-3B illustrate flowcharts for forming ceramic boards according to some embodiments.

FIGS. 4A-4E illustrate a ceramic based fan out wafer level packaging according to some embodiments.

FIGS. 5A-5B illustrate flowcharts for forming the ceramic based fan out wafer level packaging according to some embodiments.

FIGS. 6A-6C illustrate a ceramic based fan out wafer level packaging according to some embodiments.

FIGS. 7A-7B illustrate flowcharts for forming the ceramic based fan out wafer level packaging according to some embodiments.

FIGS. 8A-8C illustrate a ceramic based fan out wafer level packaging according to some embodiments.

FIGS. 9A-9B illustrate flowcharts for forming the ceramic based fan out wafer level packaging according to some embodiments.

FIGS. 10A-10C illustrate a ceramic based fan out wafer level packaging according to some embodiments.

FIGS. 11A-11B illustrate configurations of a ceramic based fan out wafer level packaging according to some embodiments.

FIGS. 12A-12B illustrate flowcharts for forming the ceramic based fan out wafer level packaging according to some embodiments.

FIGS. 13A-13C illustrate a ceramic based fan out wafer level packaging according to some embodiments.

FIGS. 14A-14B illustrate flowcharts for forming the ceramic based fan out wafer level packaging according to some embodiments.

FIGS. 15A-15B illustrate configurations for bonding ceramic boards with semiconductor chips according to some embodiments.

FIGS. 16A-16C illustrate flowcharts for bonding ceramic boards with semiconductor chips according to some embodiments.

FIGS. 17A-17B illustrate configurations for bonding ceramic boards with semiconductor chips according to some embodiments.

FIGS. 18A-18B illustrate configurations for bonding ceramic boards with semiconductor chips according to some embodiments.

FIGS. 19A-19B illustrate flowcharts for bonding ceramic boards with semiconductor chips according to some embodiments.

FIGS. 20A-20D illustrate configurations of multi-chip packages according to some embodiments.

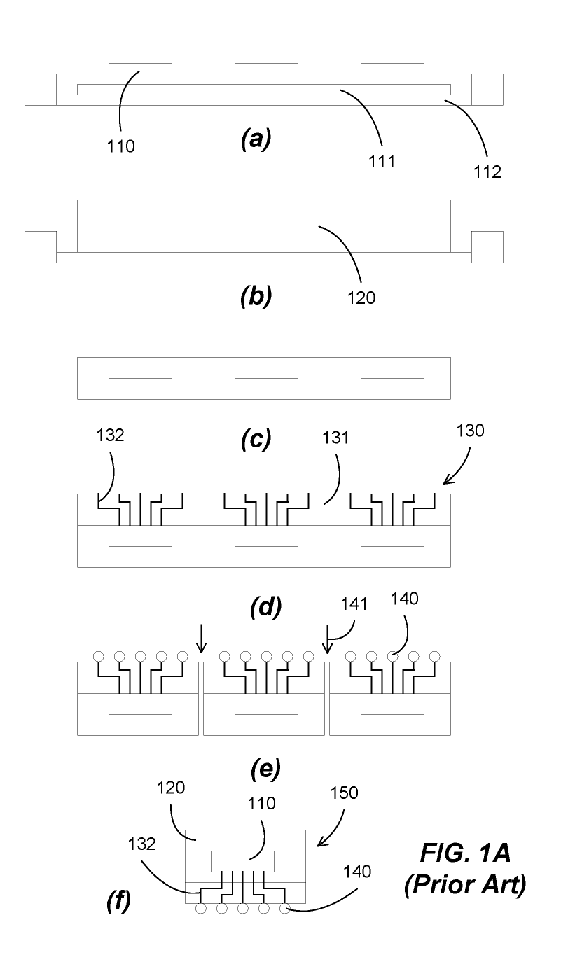

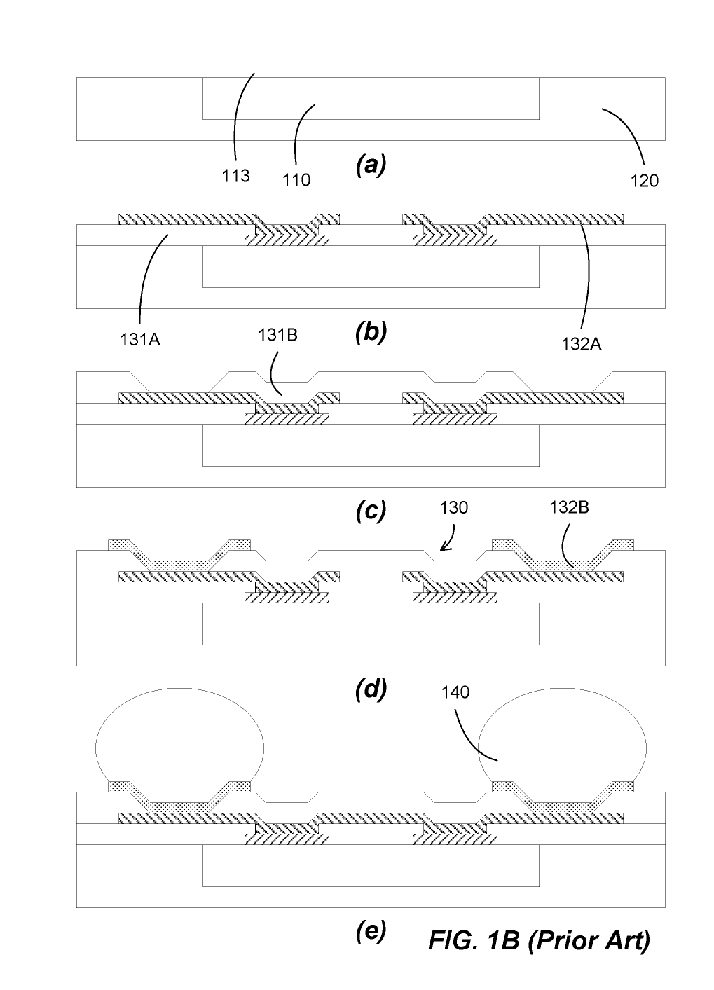

### DETAILED DESCRIPTION OF THE EMBODIMENTS

In some embodiments, the present invention discloses a packaging process including using a pre-formed ceramic board for surrounding semiconductor chips. The packaging process can provide bond pad fan out capability, and can be formed at wafer level, e.g., before a singulation process to separate the individual chip packages. The ceramic board can have thermal expansion coefficient similar to that of silicon, thus can allow for higher reliability for the interconnects spanning across the semiconductor chips and the ceramic board. For example, the thermal expansion coefficient of the ceramic board material can be less than 50% different, less than 20% different, less than 15% different, less than 10% different, or less than 5% different from the thermal expansion coefficient of silicon.

In some embodiments, a ceramic board can be formed with chip size pockets, e.g., recesses on the ceramic board having the size of the semiconductor chips to accommodate the semiconductor chips. The chip size pockets can be sized as to provide a snug fit for the semiconductor chips, thus the ceramic board can form a ceramic collar around the individual semiconductor chips. In some embodiments, an adhesive layer or a filler material can be disposed between the semiconductor chips and the ceramic pockets, for example, to ensure a close-fitting and to secure the semiconductor chips to the ceramic board. The semiconductor chips can be placed flush in the ceramic pockets, e.g., a surface of the semiconductor chips is flush with a surface of the ceramic board.

In some embodiments, the ceramic board can include interconnect lines and vias, together with embedded passive devices such as resistors and capacitors.

In some embodiments, a redistribution layer can be provided, for example, on an opposite side of the ceramic board, e.g., coupling to the ceramic board and to the semiconductor chips.

In some embodiments, the ceramic board can include a multilayer ceramic substrate, which can be formed using low temperature co-fired ceramic (LTCC). Ceramic green tapes can be stacked together for forming multiple ceramic layers. Thick film inks or pastes can be used for forming conducting patterns, e.g., interconnect lines in the layers. Thick film inks or pastes can also be used in the construction of vias, which are layer-to-layer interconnections, e.g., connecting the interconnect lines in different layers.

The ceramic green tape can be made by casting a paint-like slurry containing powders of a suitable ceramic and glass, with a polymeric binder dissolved in organic solvents, on a polymer film such as Mylar.

Examples of polymeric binders are butadiene, or Butvar, Poly-methyl methacrylate (PMMA). Mixtures of alcohols, such as Isopropyl alcohol, (IPA), and methanol, or ketones such as methyl iso-butyl-ketones (MIBK) are common solvents and vehicles for the slurry. After the solvents evaporate, the paper thin and rubbery green tape, now consisting ceramic and glass particles in a matrix of the polymeric binder, is cut to size with alignment holes at the corners.

Via holes can be formed by punching at the required locations by automated mechanical methods using a programmable die and punch set, or by laser drilling. The conductor patterns are printed on to the green tape layers, using screens or stencils cut in metal foil, and the via holes are also filled with the same or similar conductor inks.

The green tape layers are stacked in the required order and in good alignment between the layers, and laminated at a temperature of about 100° C., and pressures of between 250-1000 psi in a laminating press, to obtain a monolithic ‘green laminate’. The green laminate is then sintered' by a programmed heating regimen, in suitable furnace ambient, first to completely remove the polymeric binder, and subsequently to sinter the ceramic powder, the metal particles in the conductor lines and vias, to obtain a monolithic sintered ceramic substrate with interconnected, buried and surface conductor patterns.

Commonly used ceramic powder in multilayer substrates is alumina, which would constitute from 80-96% by weight in the green tape with certain alkaline earth alumino-silicate glasses the remainder. When alumina is used as the ceramic, its high sintering temperatures requires the use of molybdenum or tungsten inks to form the conductors. A good description of such multilayer substrates, hereby incorporated by reference in its entirety, including a detailed description of the steps in their fabrication, is given by in “Microelectronic Packaging” by A. R. Blodgett & D. R. Barbour, Scientific American, V 249 (1), pp 86-96 (1983). Because of the high temperatures (>1400° C.) involved in the fabrication, this technology is commonly referred to as High Temperature Co-fired Ceramic, (HTTC) technology.

Certain special glass compositions whose powders sinter well between 800° C.-1000° C., while simultaneously becoming crystalline, are useful in fabricating a lower temperature version of this technology in order to enable the incorporation highly conductive thick film metallurgy of copper, silver, or gold. Compositions consisting of physical mixtures of ceramic powders, usually alumina, with significant volume fraction of glasses that soften and flow at temperatures well below 1000° C. are also used for fabricating such multilayer structures. This technology for fabricating multilayer structures at these relatively lower temperatures to be compatible with thick film inks of silver, copper or gold, is commonly referred to as Low Temperature Co-fired Ceramic (LTCC) technology.

The total shrinkage of the green laminate on the way to full densification is about 50% by volume. To keep the dimension precision in the lateral dimensions, e.g., x and y directions, contact sheets can be disposed on top and bottom of the stack of green tapes, e.g., co-laminated to the top and bottom of the LTCC green laminates. The contact sheets contain materials that do not sinter and thus do not densify, thus can completely suppress the lateral shrinkage of the substrates, forcing the entire shrinkage of the green laminate to take place in the z, e.g., thickness, direction.

The contact sheets can include a refractory ceramic such as alumina. During sintering of the LTCC substrate, e.g., the stack of green tapes, in the temperature range of 800° C.-1000° C., the ceramic powder in the topmost and bottommost contact sheet layers, does not densify and, thereby, prevents the lateral shrinkage of LTCC layers in between. This, in turn, forces the LTCC layers to densify totally in the z, or thickness direction. After the substrate is fully sintered and cooled, the inert contact layers, now reduced to a loose agglomeration of the inert ceramic powder, can be easily removed with a jet of water or air and the LTCC substrate is finished with plating or other operations for use as packages for semiconductor devices.

In some embodiments, the ceramic board can include via extenders or studs, which are electrically connected to either the vias or the interconnect lines in the multilayer ceramic substrate, and which are protruded above the surfaces of the multilayer ceramic substrate. The via extenders can be formed as extensions of the vias. The vias extenders can be formed similar to the formation of the vias, with the exception is that the layer in which the via extenders are embedded therein is removed, thus exposing the via extenders.

The via extenders can be formed in the contact layers. For example, top side via extenders can be formed in the topmost contact sheet, and bottom side via extenders can be formed in the bottommost contact sheet. The via extenders can be formed in the contact sheet in a same way as to form the vias. The contact sheet with the via structures can be laminated on the top or bottom of the stack of the green laminates. After the LTCC substrate is fully sintered, the inert ceramic layers are removed by blowing off with a jet of air or of water. This exposes the vias in the contact sheet, forming the via-extenders or studs, emerging from outermost layers of the LTCC substrate, and attached firmly to the vias or interconnect lines underneath.

In some embodiments, ceramic boards with or without interconnect lines, vias and via extenders can be fabricated for device packaging. Compositions of the LTCC can include a MgO—Al2O3_SiO2 glass composition, having MgO in the range of 15-28% by weight, Al2O3 in the range of 9-15% by weight, the remainder being silica, except for less than 2% of nucleating agents such as TiO2, ZrO2, P2O5, or B2O3. The glass powder of this composition fully densifies and crystallizes in the temperature range of 850 C to 950 C, thereby co-sintering with thick film silver or copper pastes. Furthermore, the resulting ceramic has a dielectric constant of about 5, which is very good for packaging application. It has the additional benefit of having thermal expansion coefficient closely matched to that of silicon, e.g., less than 5% difference with the thermal expansion coefficient of silicon.

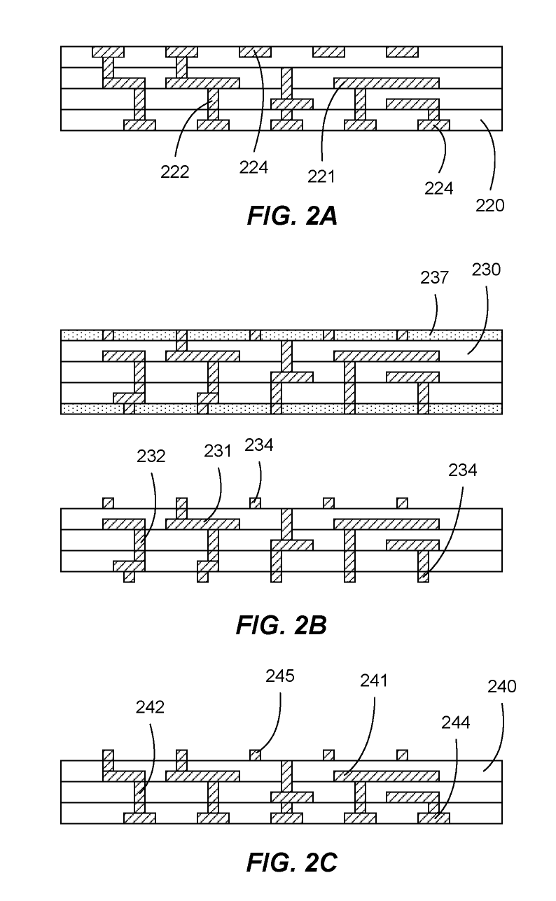

FIGS. 2A-2C illustrate configurations for ceramic boards according to some embodiments. In FIG. 2A, a stack of green laminates 220 can be formed. Interconnect lines 221 can be formed in the green laminates, forming lines for connecting different parts of the substrate. Vias 222 can be embedded in the green laminates, for connecting interconnect lines 221. Terminal pads 224 can be formed in the outermost layers of the green laminates, for contacting the interconnect lines. After the formation, the ceramic board can be sintered. In some embodiments, contact sheets can be used to prevent shrinkage in the lateral dimensions, forcing the green laminates to shrink only in the thickness direction. After sintering, the contact sheets can be removed.

In FIG. 2B, a stack of green laminates 230 can be formed. Interconnect lines 231 can be formed in the green laminates, forming lines for connecting different parts of the substrate. Vias 232 can be embedded in the green laminates, for connecting interconnect lines 231. Via extenders or studs 234 can be formed in the outermost layers of the green laminates, which can be contact sheets, e.g., materials not sinterable. After the formation, the ceramic board can be sintered. The contact sheets can be used to prevent shrinkage in the lateral dimensions, forcing the green laminates to shrink only in the thickness direction. After sintering, the contact sheets can be removed, exposing the vias in the contact sheets, forming the via extenders 234.

In FIG. 2C, a stack of green laminates 240 can be formed. Interconnect lines 241 can be formed in the green laminates, forming lines for connecting different parts of the substrate. Vias 242 can be embedded in the green laminates, for connecting interconnect lines 241. Terminal pads 244 and via extenders 245 can be formed in the outermost layers of the green laminates. For example, the terminal pads can be formed in a bottom side of the ceramic board. The via extenders can be formed in a top side of the ceramic board. In some embodiments, a combination of terminal pads and via extenders can be formed in a same side of the ceramic board.

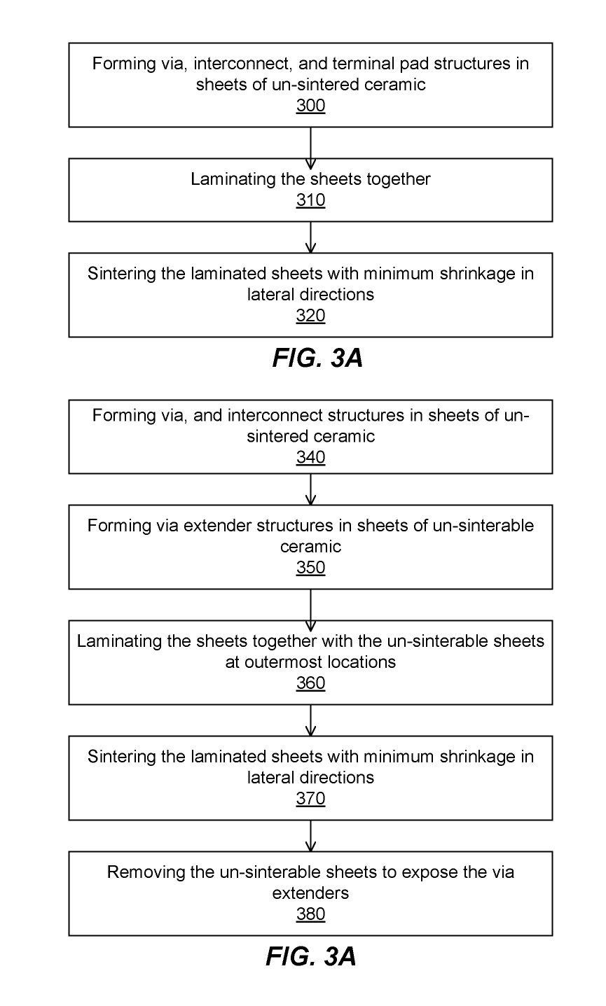

FIGS. 3A-3B illustrate flowcharts for forming ceramic boards according to some embodiments. In FIG. 3A, a ceramic board can include terminal pads on top side, bottom side, or on both sides. The terminal pads can be used for connection. Operation 300 forms via, interconnect, and terminal pad structures in sheets of un-sintered ceramic, such as green tapes. Operation 310 laminates the sheets together, with optional un-sinterable sheets at top and bottom of the stack of sheets. Recesses or pockets can be formed, for example, in the top sheets. The recesses can be configured to accept semiconductor chips. Operation 320 sinters the laminated sheets with minimum shrinkage in lateral directions, for example, due to the un-sinterable sheets.

In FIG. 3B, a ceramic board can include via extenders on top side, bottom side, or on both sides. The via extenders can be used for connection. Operation 340 forms via, and interconnect structures in sheets of un-sintered ceramic. Operation 350 forms via extender structures in sheets of un-sinterable ceramic. Operation 360 laminates the sheets together with the un-sinterable sheets at outermost locations. Recesses or pockets can be formed, for example, in the top sheets. The recesses can be configured to accept semiconductor chips. Operation 370 sinters the laminated sheets with minimum shrinkage in lateral directions. Operation 380 removes the un-sinterable sheets to expose the via extenders.

In some embodiments, ceramic boards having both terminal pads and via extenders can be formed. For example, the terminal pads can be on one side of the ceramic board. The via extenders can be on an opposite side of the ceramic board. Alternatively, both terminal pads and via extenders can be on one side of the ceramic board.

In some embodiments, the present invention discloses methods, and semiconductor chip packages using the methods, to form semiconductor chip packages with fan out capability, e.g., the packages having the terminal pads at a larger separation as compared to that of the bond pads in the semiconductor chips, and at wafer level, e.g., many semiconductor chip packages are formed in a large substrate, e.g., typically the size of a wafer, for ease of assembling and testing, before dicing into individual semiconductor chip packages.

In some embodiments, a pre-formed ceramic board, such as one made using low-temperature co-fired ceramic LTCC disclosed above, can be made with drop-in chip size pockets, sized to fit and receive diced chips to form a ceramic collar around them. After placing the diced chips in the pockets, a thin film redistribution layer (RDL) can be formed on the combined surfaces of the chip and the ceramic frame around it. Solder balls can be attached on the terminal pads of the redistribution layer, before dicing the ceramic board to form individual chip packages with fan out terminal pads.

The ceramic board can be used to replace the polymer molding layer, which forms a collar or frame around the chips, which is arranged on a temporary substrate. The ceramic based fan out wafer level package, e.g., the same package structure as in the fan out wafer level package process, is achieved but with a pre-formed ceramic panel with chip-size array of chip size receptacles into which the diced chips are simply placed or dropped-in.

In today's FOWLP, the area array pads are used to accommodate the Ball Grid Array (BGA) solder balls. These area array pads will be sitting partly on the silicon and partly on the polymer. Therefore, these area array pads may fail to behave the same due to natural changes in adhesion, stress, and other variability. This may have a negative impact on reliability. Further, today's FOWLP requires many processes, each of which adds cost and failure potential, such as the use of new materials, such as the molding material.

In contrast, the ceramic-based FOWLP avoids this issue, e.g., offering advantages to the industry of improved structure, performance easier manufacture, and reliability. The ceramic frame is created first, into which the individual silicon chips are placed. The RDL and the area array pads will be sitting on silicon and on ceramic, which have similar adhesion and CTE characteristics.

In addition, the LTCC manufacturing infrastructure already exists and simply needs to be ramped up to provide the necessary volumes. Unlike in the case of new material systems, with concomitant of the polymer case, there can be no new materials, equipment, tools, or other concerns with the present ceramic based FOWLP process. The ceramic template is made outside of the fab in a LTCC fab to exacting standards and brought into the wafer fab or packaging house clean and ready to use. This will be a high yielding and very cost-effective process, especially when using known good dies. The strong and rigid ceramic supports the thin dies, and when made to be CTE close to silicon such as our cordierite-based LTCC ceramic. It will withstand subsequent thermal processes, such as BGA solder reflow, without stressing the thin dies.

In some embodiments, the package structure can include a ceramic support and frame around the good semiconductor chips, with a common RDL structure connecting to suitable area array pads on both, on to which BGA solder balls are formed. The ceramic can be made of alumina, cordierite glass-ceramic, or aluminum nitride having high thermal conductivity. For example, a material can be the cordierite-based (MgO—Al2O3—SiO2) glass-ceramics, because of good dense sintering at below 1000 C, its high strengths, low k, and CTE matching to silicon. The ceramic board can be fabricated using a laminated green sheet process. This approach also allow for the incorporation of passive components, such as capacitors and resistors, in the internal layers of the LTCC. The zero lateral shrinkage sintering process can make for distortion-free passive device fabrication in the LTCC layer.

In some embodiments, the ceramic board can include thermal heat sink, such as forming thermal vias under the chip area with thick film silver or copper conductors. Further multilayer LTCC can allow for internally connecting adjacent devices in a multichip or multi-device configuration of FOWLP.

In some embodiments, underfill can be omitted because the ceramic board is CTE (coefficient of thermal expansion) matched with the silicon of the semiconductor chips. The underfill can be included make the solder balls more reliable. The resulting packages are CTE matched, which means there is no stress in the solder balls between the two substrates.

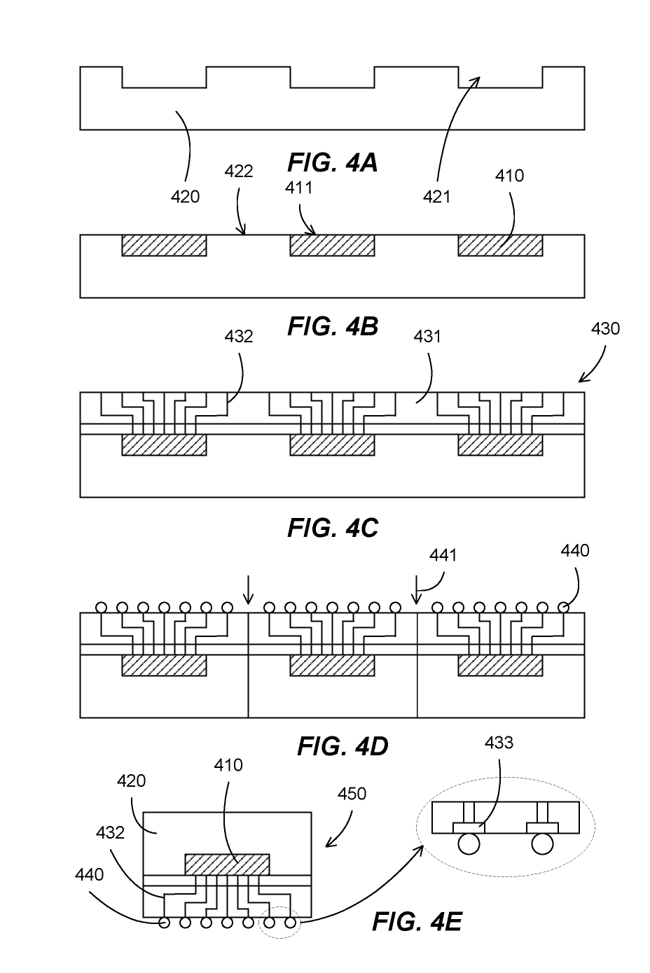

FIGS. 4A-4E illustrate a ceramic based fan out wafer level packaging according to some embodiments. In FIG. 4A, a ceramic board 420 can be formed, including pockets or recesses 421, which are configured to accept semiconductor chips 410. The ceramic board can be formed by laminating multiple sheets of sinterable ceramic materials. In FIG. 4B, semiconductor chips 410 can be placed in the pockets 421. The pockets can be designed to provide a good fitting. In some embodiments, a filling material can be placed between the chips and the pockets. An adhesion layer can also be placed between the chips and the pockets, for example, to secure the chips to the pockets. The semiconductor chips can be placed so that active surfaces, e.g., the surface 411 of the chips having the bond pads, are faced up, e.g., exposed and flush with a surface 422 of the ceramic board.

In FIG. 4C, a redistribution layer 430 can be formed on the combined surfaces of the semiconductor chips and the ceramic board. The redistribution layer 430 can include one or more dielectric layer 431, together with interconnect lines and vias 432, which provide a fan out of the bond pads of the semiconductor chips to terminal pads 433 on top of the redistribution layer 430.

In FIG. 4D, solder balls 440 are attached to the terminal pads 433 of the ceramic board. The composite substrate can be diced 441 into individual semiconductor chip packages 450 (FIG. 4E). Other configurations can be used, such as via extenders for coupling with the solder balls instead of terminal pads.

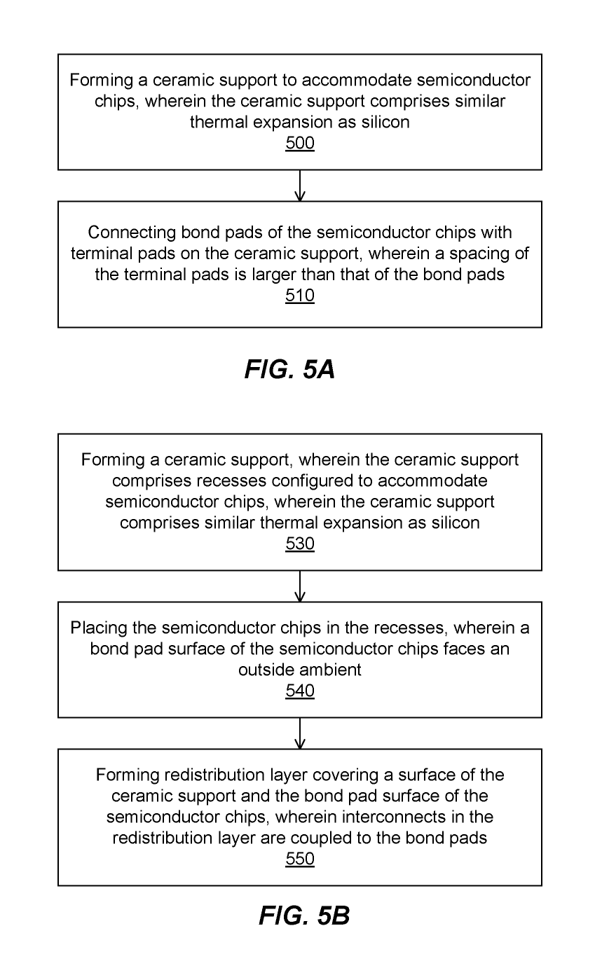

FIGS. 5A-5B illustrate flowcharts for forming the ceramic based fan out wafer level packaging according to some embodiments. In FIG. 5A, operation 500 forms a ceramic support to accommodate semiconductor chips, wherein the ceramic support comprises similar thermal expansion as silicon. Operation 510 connects bond pads of the semiconductor chips with terminal pads on the ceramic support, wherein a spacing of the terminal pads is larger than that of the bond pads.

In FIG. 5B, operation 530 forms a ceramic support, wherein the ceramic support comprises recesses configured to accommodate semiconductor chips, wherein the ceramic support comprises similar thermal expansion as silicon. Operation 540 places the semiconductor chips in the recesses, wherein a bond pad surface of the semiconductor chips faces an outside ambient. Operation 550 forms redistribution layer covering a surface of the ceramic support and the bond pad surface of the semiconductor chips, wherein interconnects in the redistribution layer are coupled to the bond pads.

In some embodiments, the present invention discloses methods to form ceramic based fan out wafer level packages, and ceramic based fan out wafer level packages formed from the methods. The methods can include forming a ceramic board, placing the semiconductor chips in the recesses, and forming a redistribution layer on the ceramic board covering the semiconductor chips, wherein the redistribution layer comprises interconnects connecting bond pads of the semiconductors to external terminal pads on the redistribution layer, wherein a first separation between the terminal pads is larger than a second separation between the bond pads.

The ceramic board can be formed by stacking first sheets of a sinterable ceramic material, wherein the stack of the first sheets comprises recesses configured to accept semiconductor chips, wherein the sinterable ceramic material comprises a thermal expansion coefficient similar to that of silicon, placing second sheets at the top and bottom of the stack of the first sheets, wherein the second sheets comprise an unsinterable ceramic material, sintering the stack of first and second sheets, and removing the second sheets.

In some embodiments, the methods can further include forming solder balls on the terminal pads. The methods can further include dicing the ceramic board to form individual packages, wherein each individual package comprises one semiconductor chip. The methods can further include coating the recesses with an adhesive layer before placing the semiconductor chips, or coating the recesses with a filler layer before placing the semiconductor chips.

In some embodiments, the similarity between the thermal expansion coefficient of the ceramic material and silicon can be less than 50%, less than 20%, less than 10%, or less than 5% different. For example, thermal expansion coefficient of silicon at 20 C is 2.56×10⁻⁶ per degree Kelvin. The thermal expansion coefficient of the ceramic material can be less than 50% different, meaning can be ranging from 1.28 to 3.84×10⁻⁶ per degree Kelvin. The thermal expansion coefficient of the ceramic material can be less than 20% different, meaning can be ranging from 2.05 to 3.07×10⁻⁶ per degree Kelvin. The thermal expansion coefficient of the ceramic material can be less than 10% different, meaning can be ranging from 2.30 to 2.82×10⁻⁶ per degree Kelvin. The thermal expansion coefficient of the ceramic material can be less than 5% different, meaning can be ranging from 2.43 to 2.69×10⁻⁶ per degree Kelvin. The thermal expansion coefficient of the ceramic material can be determined by the composition of the components of the ceramic, e.g., by choosing ceramic powder having similar thermal expansion coefficient with silicon, or by mixing different ceramic powders so that the mixture can have similar thermal expansion coefficient.

In some embodiments, each package can include multiple semiconductor chips with cross interconnect lines between the bond pads of the multiple semiconductor chips. The interconnects in the redistribution layer can cross connect multiple semiconductor chips with the external terminal pads, and the ceramic board can be diced to form individual packages, wherein each individual package comprises the multiple semiconductor chips.

In some embodiments, power and ground planes, decoupling capacitors and terminating resistors can be incorporated in the ceramic board to enhance the package performance and extend the functionality of the ceramic based fan out wafer level packages.

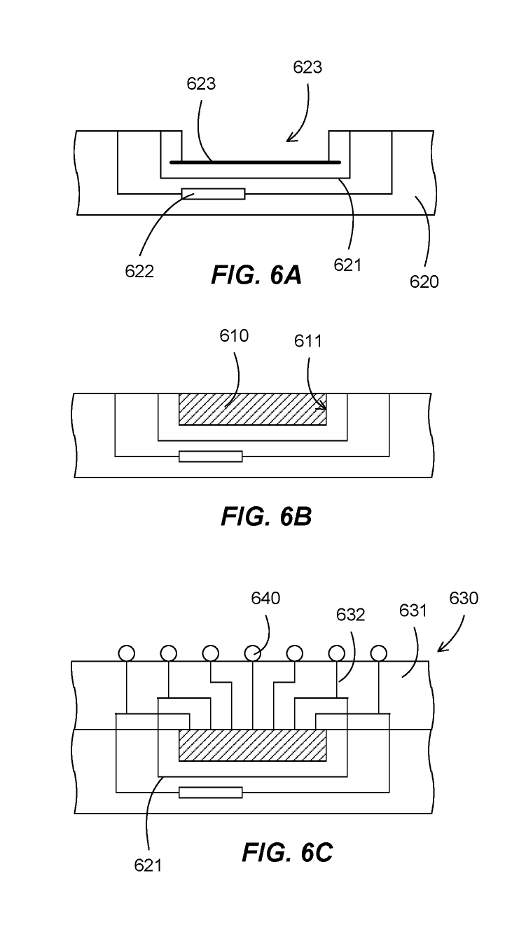

FIGS. 6A-6C illustrate a ceramic based fan out wafer level packaging according to some embodiments. In FIG. 6A, a ceramic board 620 can be formed, including pockets or recesses 623, which are configured to accept semiconductor chips 610. The ceramic board can be formed by laminating multiple sheets of sinterable ceramic materials. Interconnect lines and vias 621 can be formed in the ceramic board 620, for example, in a process described above. Passive devices 622, such as resistors, capacitors, or inductors, can also be embedded in the ceramic board. Heat sink 623, e.g., made of thermal conductive material such as silver or copper or aluminum, can be formed so that the semiconductor chips can contact the heat sink, for thermal dissipation.

In FIG. 6B, semiconductor chips 610 can be placed in the pockets. The pockets can be designed to provide a good fitting. In some embodiments, a filling material can be placed between the chips and the pockets. An adhesion layer 611 can also be placed between the chips and the pockets, for example, to secure the chips to the pockets. The semiconductor chips can be placed so that active surfaces, e.g., the surface of the chips having the bond pads, are faced up, e.g., exposed and flush with a surface of the ceramic board.

In FIG. 6C, a redistribution layer 630 can be formed on the combined surfaces of the semiconductor chips and the ceramic board. The redistribution layer 630 can include one or more dielectric layer 631, together with interconnect lines and vias 632, which provide a fan out of the bond pads of the semiconductor chips to terminal pads on top of the redistribution layer 630. The interconnect lines and vias 632 can be made to contact and link to the interconnect lines and vias 621 previously formed in the ceramic board.

Solder balls 640 are attached to the terminal pads of the ceramic board. The composite substrate can be diced into individual semiconductor chip packages.

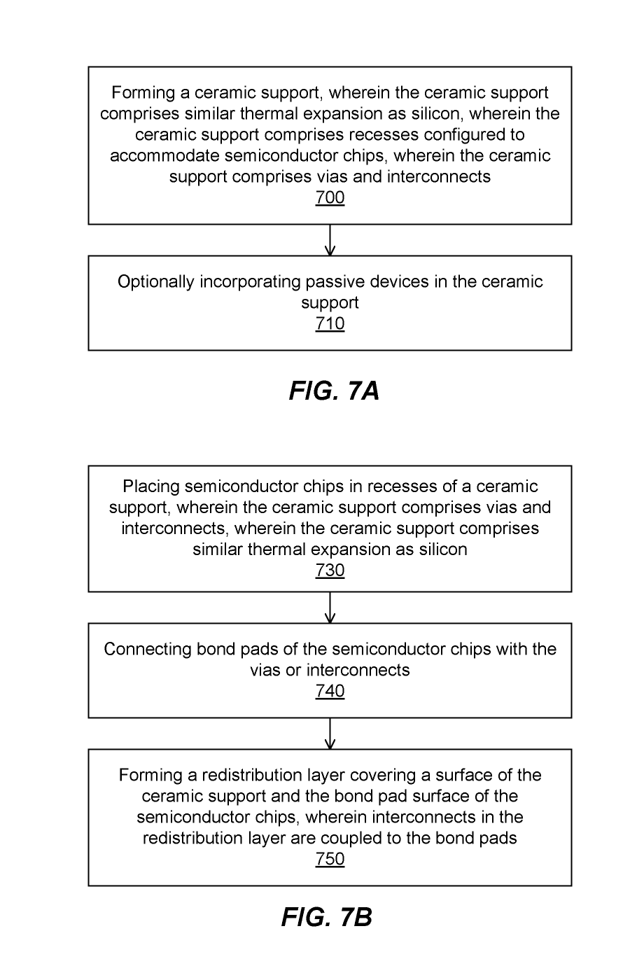

FIGS. 7A-7B illustrate flowcharts for forming the ceramic based fan out wafer level packaging according to some embodiments. In FIG. 7A, operation 700 forms a ceramic support, wherein the ceramic support comprises similar thermal expansion as silicon, wherein the ceramic support comprises recesses configured to accommodate semiconductor chips, wherein the ceramic support comprises vias and interconnects. Operation 710 optionally incorporates passive devices in the ceramic support.

In FIG. 7B, operation 730 places semiconductor chips in recesses of a ceramic support, wherein the ceramic support comprises vias and interconnects, wherein the ceramic support comprises similar thermal expansion as silicon. Operation 740 connects bond pads of the semiconductor chips with the vias or interconnects. Operation 750 forms a redistribution layer covering a surface of the ceramic support and the bond pad surface of the semiconductor chips, wherein interconnects in the redistribution layer are coupled to the bond pads.

In some embodiments, additional terminal pads can be incorporated in the ceramic board to enhance the package performance and extend the functionality of the ceramic based fan out wafer level packages.

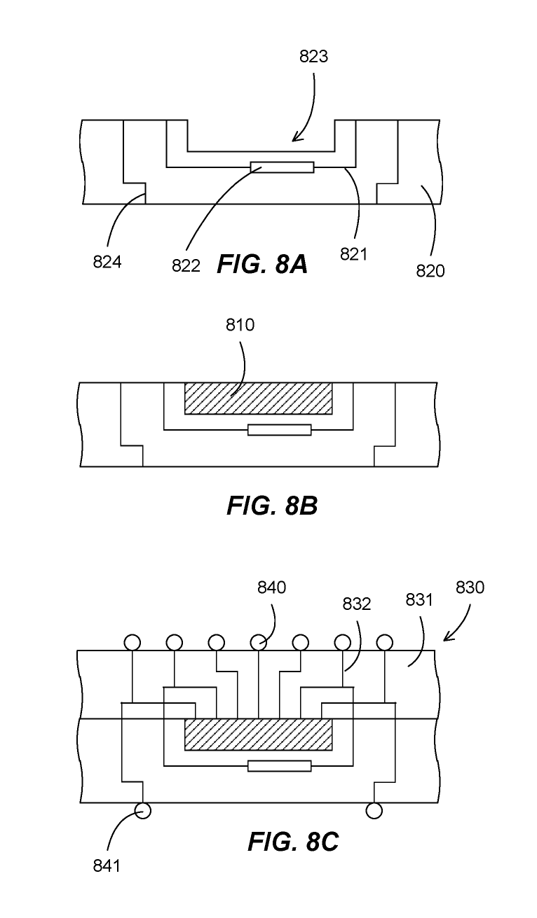

FIGS. 8A-8C illustrate a ceramic based fan out wafer level packaging according to some embodiments. In FIG. 8A, a ceramic board 820 can be formed, including pockets or recesses 823, which are configured to accept semiconductor chips 810. The ceramic board can be formed by laminating multiple sheets of sinterable ceramic materials. Interconnect lines and vias 821 can be formed in the ceramic board 820, for example, in a process described above. Passive devices 822, such as resistors, capacitors, or inductors, can also be embedded in the ceramic board. Interconnect lines and vias 824 can be extended to an external surface of the ceramic board, connecting to terminal pads disposed on a bottom side of the ceramic board.

In FIG. 8B, semiconductor chips 810 can be placed in the pockets. The pockets can be designed to provide a good fitting. In some embodiments, a filling material can be placed between the chips and the pockets. An adhesion layer can also be placed between the chips and the pockets, for example, to secure the chips to the pockets. The semiconductor chips can be placed so that active surfaces, e.g., the surface of the chips having the bond pads, are faced up, e.g., exposed and flush with a surface of the ceramic board.

In FIG. 8C, a redistribution layer 830 can be formed on the combined surfaces of the semiconductor chips and the ceramic board. The redistribution layer 830 can include one or more dielectric layer 831, together with interconnect lines and vias 832, which provide a fan out of the bond pads of the semiconductor chips to terminal pads on top of the redistribution layer 830. The interconnect lines and vias 832 can be made to contact and link to the interconnect lines and vias 821 and 824 previously formed in the ceramic board.

Solder balls 840 and 841 are attached to the terminal pads of the ceramic board. The composite substrate can be diced into individual semiconductor chip packages.

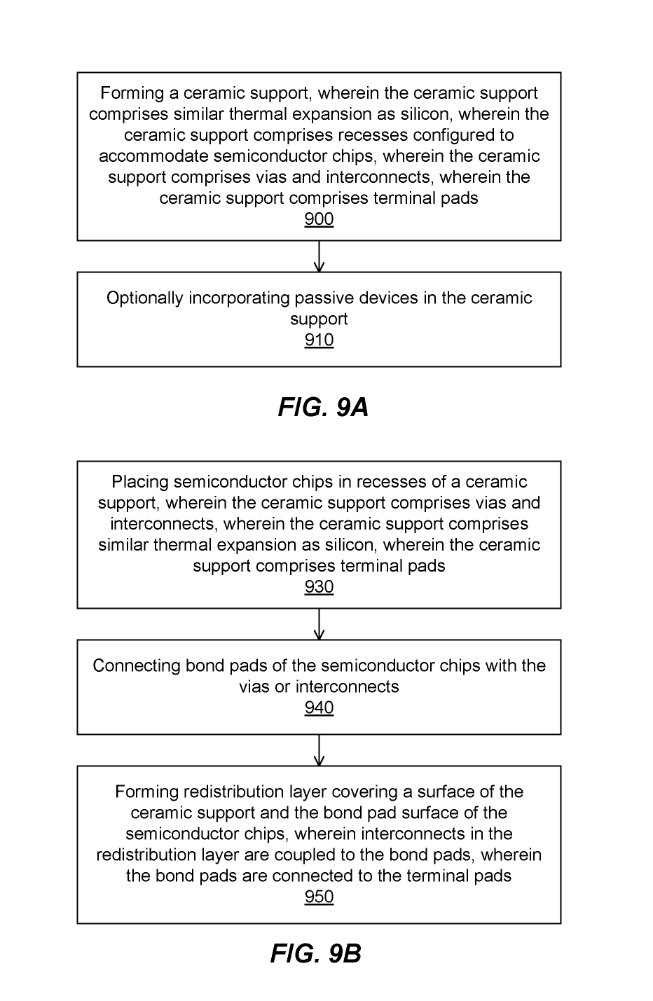

FIGS. 9A-9B illustrate flowcharts for forming the ceramic based fan out wafer level packaging according to some embodiments. In FIG. 9A, operation 900 forms a ceramic support, wherein the ceramic support comprises similar thermal expansion as silicon, wherein the ceramic support comprises recesses configured to accommodate semiconductor chips, wherein the ceramic support comprises vias and interconnects, wherein the ceramic support comprises terminal pads. Operation 910 optionally incorporates passive devices in the ceramic support.

In FIG. 9B, operation 930 places semiconductor chips in recesses of a ceramic support, wherein the ceramic support comprises vias and interconnects, wherein the ceramic support comprises similar thermal expansion as silicon, wherein the ceramic support comprises terminal pads. Operation 940 connects bond pads of the semiconductor chips with the vias or interconnects. Operation 950 forms redistribution layer covering a surface of the ceramic support and the bond pad surface of the semiconductor chips, wherein interconnects in the redistribution layer are coupled to the bond pads, wherein the bond pads are connected to the terminal pads.

In some embodiments, fan out terminal pads can be incorporated in the ceramic board, for example, to replace or to enhance the redistribution layer.

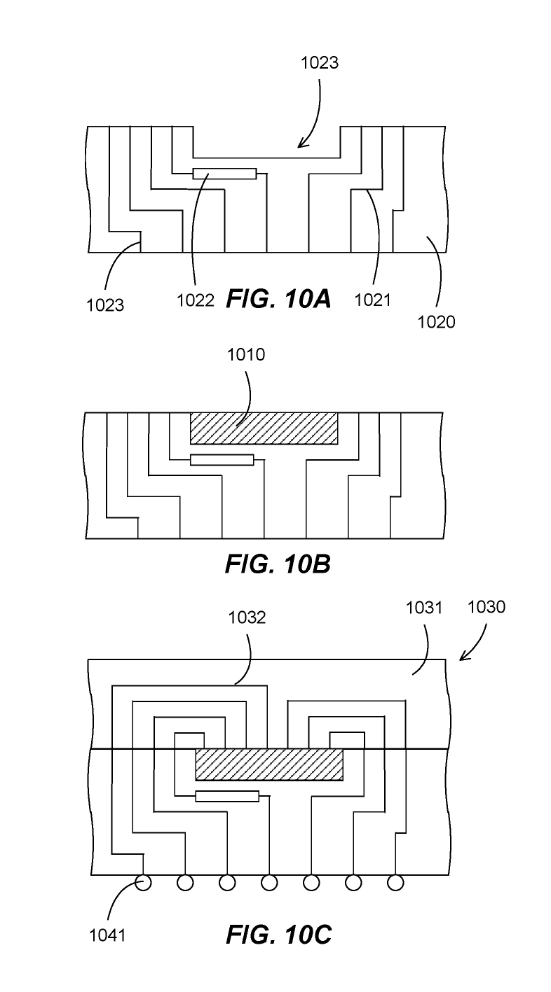

FIGS. 10A-10C illustrate a ceramic based fan out wafer level packaging according to some embodiments. In FIG. 10A, a ceramic board 1020 can be formed, including pockets or recesses 1023, which are configured to accept semiconductor chips 1010. The ceramic board can be formed by laminating multiple sheets of sinterable ceramic materials. Interconnect lines and vias 1021 can be formed in the ceramic board 1020, for example, in a process described above. Passive devices 1022, such as resistors, capacitors, or inductors, can also be embedded in the ceramic board. Interconnect lines and vias 1023 can be extended to an external surface of the ceramic board, forming a fan out of the bond pads of the semiconductor chips to the terminal pads.

In FIG. 10B, semiconductor chips 1010 can be placed in the pockets. The pockets can be designed to provide a good fitting. In some embodiments, a filling material can be placed between the chips and the pockets. An adhesion layer can also be placed between the chips and the pockets, for example, to secure the chips to the pockets. The semiconductor chips can be placed so that active surfaces, e.g., the surface of the chips having the bond pads, are faced up, e.g., exposed and flush with a surface of the ceramic board.

In FIG. 10C, a redistribution layer 1030 can be formed on the combined surfaces of the semiconductor chips and the ceramic board. The redistribution layer 1030 can include one or more dielectric layer 1031, together with interconnect lines and vias 1032, which provide a fan out of the bond pads of the semiconductor chips to terminal pads on top of the redistribution layer 1030. The interconnect lines and vias 1032 can be made to contact and link to the interconnect lines and vias 1021 and 1023 previously formed in the ceramic board.

Solder balls 1041 are attached to the terminal pads of the ceramic board. The composite substrate can be diced into individual semiconductor chip packages.

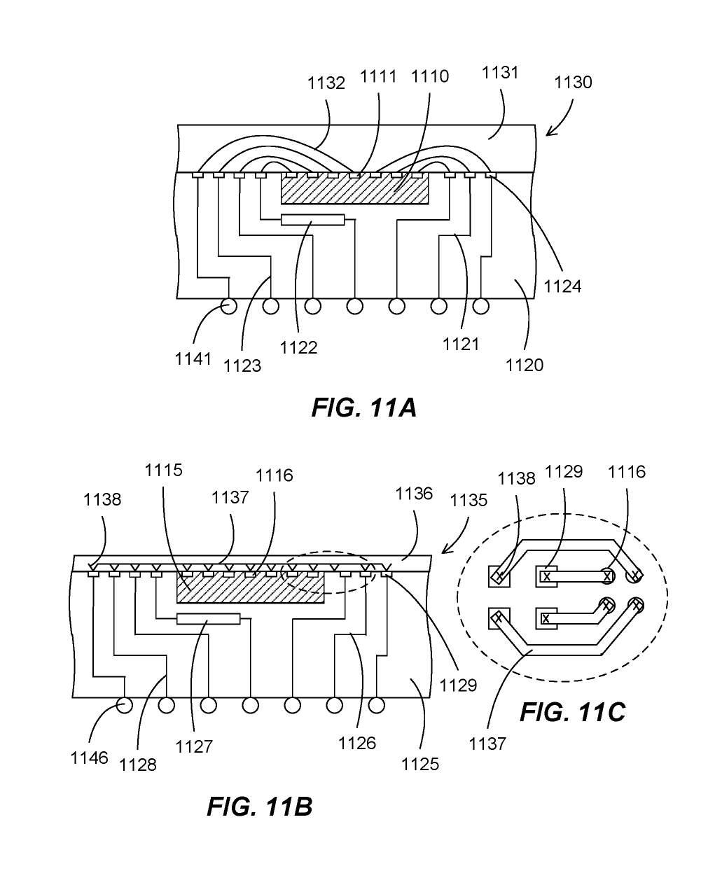

FIGS. 11A-11B illustrate configurations of a ceramic based fan out wafer level packaging according to some embodiments. In FIG. 11A, a ceramic board 1120 can be formed, including pockets or recesses 1123, which are configured to accept semiconductor chips 1110. The ceramic board can be formed by laminating multiple sheets of sinterable ceramic materials. Interconnect lines and vias 1121 can be formed in the ceramic board 1120, for example, in a process described above. Passive devices 1122, such as resistors, capacitors, or inductors, can also be embedded in the ceramic board. Interconnect lines and vias 1124 can be extended to an external surface of the ceramic board, connecting to terminal pads disposed on a bottom side of the ceramic board.

Semiconductor chips 1110 can be placed in the pockets. The pockets can be designed to provide a good fitting. In some embodiments, a filling material can be placed between the chips and the pockets. An adhesion layer can also be placed between the chips and the pockets, for example, to secure the chips to the pockets. The semiconductor chips can be placed so that active surfaces, e.g., the surface of the chips having the bond pads, are faced up, e.g., exposed and flush with a surface of the ceramic board.

A redistribution layer 1130 can be formed on the combined surfaces of the semiconductor chips and the ceramic board. The redistribution layer 1130 can include multiple wire bonds 1132, which provide a fan out of the bond pads of the semiconductor chips to terminal pads on top of the ceramic board 1120. A dielectric layer 1131 can be used to encapsulate the wire bonds. Solder balls 1141 are attached to the terminal pads of the ceramic board. The composite substrate can be diced into individual semiconductor chip packages.

In FIG. 11B, a ceramic board 1125 can be formed, including pockets or recesses 1128, which are configured to accept semiconductor chips 1115. The ceramic board can be formed by laminating multiple sheets of sinterable ceramic materials. Interconnect lines and vias 1126 can be formed in the ceramic board 1125, for example, in a process described above. Passive devices 1127, such as resistors, capacitors, or inductors, can also be embedded in the ceramic board. Interconnect lines and vias 1129 can be extended to an external surface of the ceramic board, connecting to terminal pads disposed on a bottom side of the ceramic board.

Semiconductor chips 1115 can be placed in the pockets. The pockets can be designed to provide a good fitting. In some embodiments, a filling material can be placed between the chips and the pockets. An adhesion layer can also be placed between the chips and the pockets, for example, to secure the chips to the pockets. The semiconductor chips can be placed so that active surfaces, e.g., the surface of the chips having the bond pads, are faced up, e.g., exposed and flush with a surface of the ceramic board.

A redistribution layer 1135 can be formed on the combined surfaces of the semiconductor chips and the ceramic board. The redistribution layer 1135 can include an interconnect sheet having interconnect lines 1137. A dielectric layer 1136 can be used to encapsulate the interconnect sheet. Solder balls 1146 are attached to the terminal pads of the ceramic board. The composite substrate can be diced into individual semiconductor chip packages.

FIG. 11C shows a configuration for an interconnect sheet. The interconnect sheet, e.g., a then polymer sheet with an embedded pattern of interconnect lines 1137, can be embedded in an encapsulating layer 1136, such as the redistribution layer. The interconnect lines 1137 can be bonded 1138, e.g., by a laser bonding process, to connect the interconnect lines with the terminal pads and the bond pads. The interconnect lines can provide a fan out of the bond pads of the semiconductor chips to terminal pads on top of the ceramic board 1125.

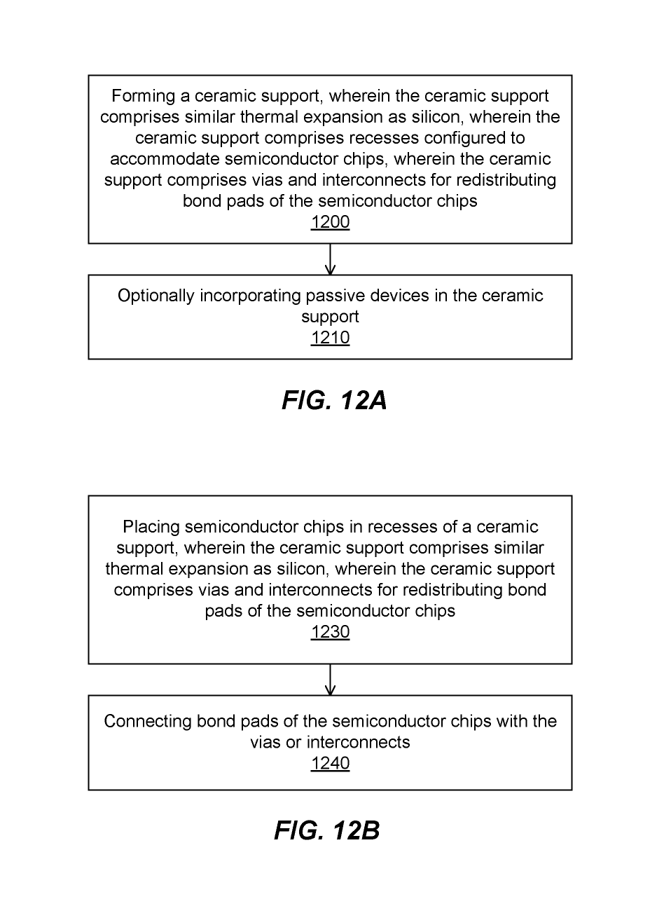

FIGS. 12A-12B illustrate flowcharts for forming the ceramic based fan out wafer level packaging according to some embodiments. In FIG. 12A, operation 1200 forms a ceramic support, wherein the ceramic support comprises similar thermal expansion as silicon, wherein the ceramic support comprises recesses configured to accommodate semiconductor chips, wherein the ceramic support comprises vias and interconnects for redistributing bond pads of the semiconductor chips. Operation 1210 optionally incorporates passive devices in the ceramic support.

In FIG. 12B, operation 1230 places semiconductor chips in recesses of a ceramic support, wherein the ceramic support comprises similar thermal expansion as silicon, wherein the ceramic support comprises vias and interconnects for redistributing bond pads of the semiconductor chips. Operation 1240 connects bond pads of the semiconductor chips with the vias or interconnects.

In some embodiments, the present invention discloses methods to form ceramic based fan out wafer level packages, and ceramic based fan out wafer level packages formed from the methods. The methods can include forming a ceramic board, placing the semiconductor chips in the recesses, and connecting the bond pads to the interconnect lines.

The ceramic board can be formed by stacking first sheets of a sinterable ceramic material, wherein the sinterable ceramic material comprises a thermal expansion coefficient similar to that of silicon, placing second sheets at the top and bottom of the stack of the first sheets, wherein the second sheets comprise an unsinterable ceramic material, wherein the stack of the first and second sheets comprises recesses configured to accept semiconductor chips, wherein the stack of the first and second sheets comprises terminal pads, wherein a first separation between the terminal pads is larger than a second separation between bond pads of the semiconductor chips, wherein the stack of the first and second sheets comprises interconnect lines coupling to the terminal pads for redistributing the bond pads, sintering the stack of first and second sheets, and removing the second sheets.

In some embodiments, forming the ceramic board can further include embedding at least a passive component in the stack of the first and second sheets before sintering the stack of first and second sheets. The terminal pads can include via extenders protruded from the ceramic board or via pads embedded in a surface of the ceramic board.

In some embodiments, the methods can further include forming solder balls on the terminal pads. The methods can further include dicing the ceramic board to form individual packages, wherein each individual package comprises one semiconductor chip. The methods can further include coating the recesses with an adhesive layer before placing the semiconductor chips, or coating the recesses with a filler layer before placing the semiconductor chips.

In some embodiments, the similarity between the thermal expansion coefficient of the ceramic material and silicon can be less than 50%, less than 20%, less than 10%, or less than 5% different. For example, thermal expansion coefficient of silicon at 20 C is 2.56×10⁻⁶ per degree Kelvin. The thermal expansion coefficient of the ceramic material can be less than 50% different, meaning can be ranging from 1.28 to 3.84×10⁻⁶ per degree Kelvin. The thermal expansion coefficient of the ceramic material can be less than 20% different, meaning can be ranging from 2.05 to 3.07×10⁻⁶ per degree Kelvin. The thermal expansion coefficient of the ceramic material can be less than 10% different, meaning can be ranging from 2.30 to 2.82×10⁻⁶ per degree Kelvin. The thermal expansion coefficient of the ceramic material can be less than 5% different, meaning can be ranging from 2.43 to 2.69×10⁻⁶ per degree Kelvin. The thermal expansion coefficient of the ceramic material can be determined by the composition of the components of the ceramic, e.g., by choosing ceramic powder having similar thermal expansion coefficient with silicon, or by mixing different ceramic powders so that the mixture can have similar thermal expansion coefficient.

In some embodiments, each package can include multiple semiconductor chips with cross interconnect lines between the bond pads of the multiple semiconductor chips. The interconnects in the redistribution layer can cross connect multiple semiconductor chips with the external terminal pads, and the ceramic board can be diced to form individual packages, wherein each individual package comprises the multiple semiconductor chips.

In some embodiments, the bond pads can be connected to the interconnect lines in a redistribution layer. The redistribution layer can further include second terminal pads, wherein the redistribution layer comprises interconnects connecting the bond pads to the second terminal pads.

In some embodiments, connecting the bond pads to the interconnect lines can include multiple interconnect lines embedded in one or more layers of dielectric. Connecting the bond pads to the interconnect lines can include multiple wires connected to the bond pads in a wire bonding process. Connecting the bond pads to the interconnect lines can include an interconnect sheet having conductive lines with pad endpoints, wherein the pad endpoints are connected to the bond pads by a laser bonding process. Connecting the bond pads to the interconnect lines can include connecting the bond pads to pads in the ceramic board, wherein the pads are coupled to the interconnect lines.

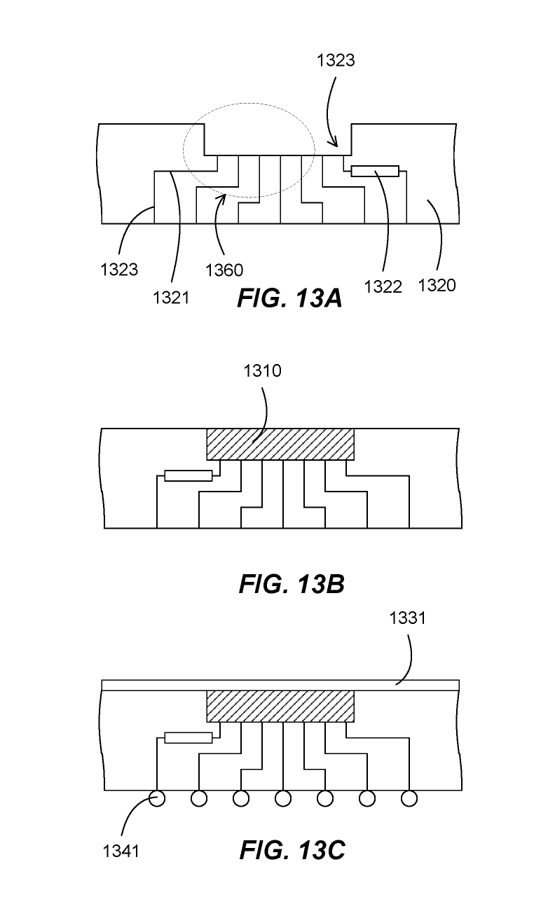

In some embodiments, fan out terminal pads can be incorporated in the ceramic board, acting as a redistribution layer. FIGS. 13A-13C illustrate a ceramic based fan out wafer level packaging according to some embodiments. In FIG. 13A, a ceramic board 1320 can be formed, including pockets or recesses 1323, which are configured to accept semiconductor chips 1310. The ceramic board can be formed by laminating multiple sheets of sinterable ceramic materials. Interconnect lines and vias 1321 can be formed in the ceramic board 1320, for example, in a process described above. Passive devices 1322, such as resistors, capacitors, or inductors, can also be embedded in the ceramic board. Interconnect lines and vias 1323 can be extended to an external surface of the ceramic board, forming a fan out of the bond pads of the semiconductor chips to the terminal pads.

In FIG. 13B, semiconductor chips 1310 can be placed in the pockets. The pockets can be designed to provide a good fitting. In some embodiments, a filling material can be placed between the chips and the pockets. An adhesion layer can also be placed between the chips and the pockets, for example, to secure the chips to the pockets. The semiconductor chips can be placed so that active surfaces, e.g., the surface of the chips having the bond pads, are faced down, e.g., embedded in the ceramic board. The backside of the semiconductor chips, e.g., the opposite side of the active surface, can be flush with a surface of the ceramic board. The placing of the semiconductor chips can be configured so that the bond pads of the semiconductor chips align with the terminal pads or the via extenders of the ceramic board. Solder balls can be used to bond the bond pads with the terminal pads or the via extenders.

In FIG. 13C, an encapsulate layer 1331 can be formed on the combined surfaces of the backside of the semiconductor chips and the ceramic board. Solder balls 1341 are attached to the terminal pads of the ceramic board. The composite substrate can be diced into individual semiconductor chip packages.

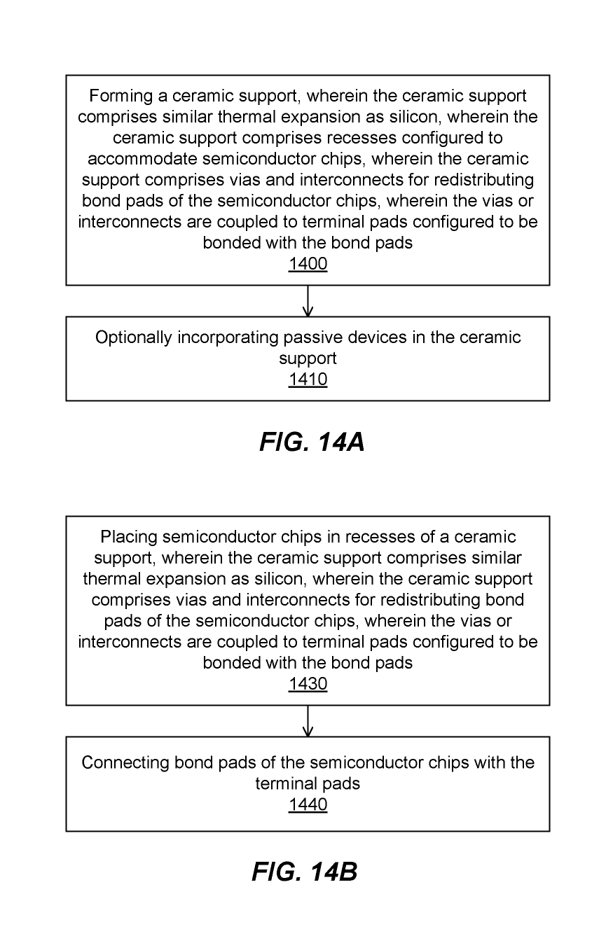

FIGS. 14A-14B illustrate flowcharts for forming the ceramic based fan out wafer level packaging according to some embodiments. In FIG. 14A, operation 1400 forms a ceramic support, wherein the ceramic support comprises similar thermal expansion as silicon, wherein the ceramic support comprises recesses configured to accommodate semiconductor chips, wherein the ceramic support comprises vias and interconnects for redistributing bond pads of the semiconductor chips, wherein the vias or interconnects are coupled to terminal pads configured to be bonded with the bond pads. Operation 1410 optionally incorporates passive devices in the ceramic support.

In FIG. 14B, operation 1430 places semiconductor chips in recesses of a ceramic support, wherein the ceramic support comprises similar thermal expansion as silicon, wherein the ceramic support comprises vias and interconnects for redistributing bond pads of the semiconductor chips, wherein the vias or interconnects are coupled to terminal pads configured to be bonded with the bond pads. Operation 1440 connects bond pads of the semiconductor chips with the terminal pads.

In some embodiments, the present invention discloses methods to form ceramic based fan out wafer level packages, and ceramic based fan out wafer level packages formed from the methods. The methods can include forming a ceramic board, placing the semiconductor chips in the recesses, wherein the bond pads are configured to face the second terminal pads for bonding with the second terminal pads, and forming an encapsulate layer on the ceramic board covering the semiconductor chips.

The ceramic board can be formed by stacking first sheets of a sinterable ceramic material, placing second sheets at the top and bottom of the stack of the first sheets, wherein the second sheets comprise an unsinterable ceramic material, wherein the stack of the first and second sheets comprises recesses configured to accept semiconductor chips, wherein the stack of the first and second sheets comprises first terminal pads and second terminal pads, wherein a first separation between the first terminal pads is larger than a second separation between bond pads of the semiconductor chips, wherein the stack of the first and second sheets comprises interconnect lines coupling to the first terminal pads to the second terminal pads, sintering the stack of first and second sheets, and removing the second sheets.

In some embodiments, forming the ceramic board can further include embedding at least a passive component in the stack of the first and second sheets before sintering the stack of first and second sheets. The terminal pads can include via extenders protruded from the ceramic board or via pads embedded in a surface of the ceramic board.

In some embodiments, the methods can further include forming solder balls on the terminal pads. The methods can further include dicing the ceramic board to form individual packages, wherein each individual package comprises one semiconductor chip. The methods can further include coating the recesses with an adhesive layer before placing the semiconductor chips, or coating the recesses with a filler layer before placing the semiconductor chips.

In some embodiments, the similarity between the thermal expansion coefficient of the ceramic material and silicon can be less than 50%, less than 20%, less than 10%, or less than 5% different. For example, thermal expansion coefficient of silicon at 20 C is 2.56×10⁻⁶ per degree Kelvin. The thermal expansion coefficient of the ceramic material can be less than 50% different, meaning can be ranging from 1.28 to 3.84×10⁻⁶ per degree Kelvin. The thermal expansion coefficient of the ceramic material can be less than 20% different, meaning can be ranging from 2.05 to 3.07×10⁻⁶ per degree Kelvin. The thermal expansion coefficient of the ceramic material can be less than 10% different, meaning can be ranging from 2.30 to 2.82×10⁻⁶ per degree Kelvin. The thermal expansion coefficient of the ceramic material can be less than 5% different, meaning can be ranging from 2.43 to 2.69×10⁻⁶ per degree Kelvin. The thermal expansion coefficient of the ceramic material can be determined by the composition of the components of the ceramic, e.g., by choosing ceramic powder having similar thermal expansion coefficient with silicon, or by mixing different ceramic powders so that the mixture can have similar thermal expansion coefficient.

In some embodiments, each package can include multiple semiconductor chips with cross interconnect lines between the bond pads of the multiple semiconductor chips. The interconnects in the redistribution layer can cross connect multiple semiconductor chips with the external terminal pads, and the ceramic board can be diced to form individual packages, wherein each individual package comprises the multiple semiconductor chips.

In some embodiments, the encapsulate layer comprises interconnects for connecting the interconnect lines.

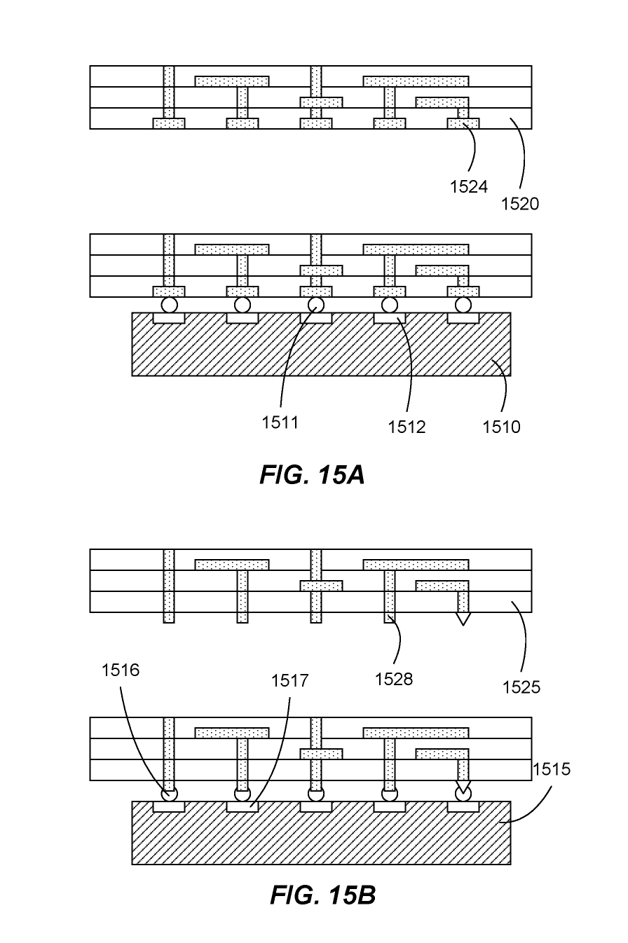

FIGS. 15A-15B illustrate configurations for bonding ceramic boards with semiconductor chips according to some embodiments. In FIG. 15A, the ceramic board 1520 can have terminal pads 1524, which can be bonded to the bond pads 1512 of the semiconductor chips 1510 through solder balls 1511. In FIG. 15B, the ceramic board 1525 can have via extenders 1528, which can be bonded to the bond pads 1517 of the semiconductor chips 1515 through solder balls 1516. The via extenders can have sharp tips to assist in contacting the bond pads.

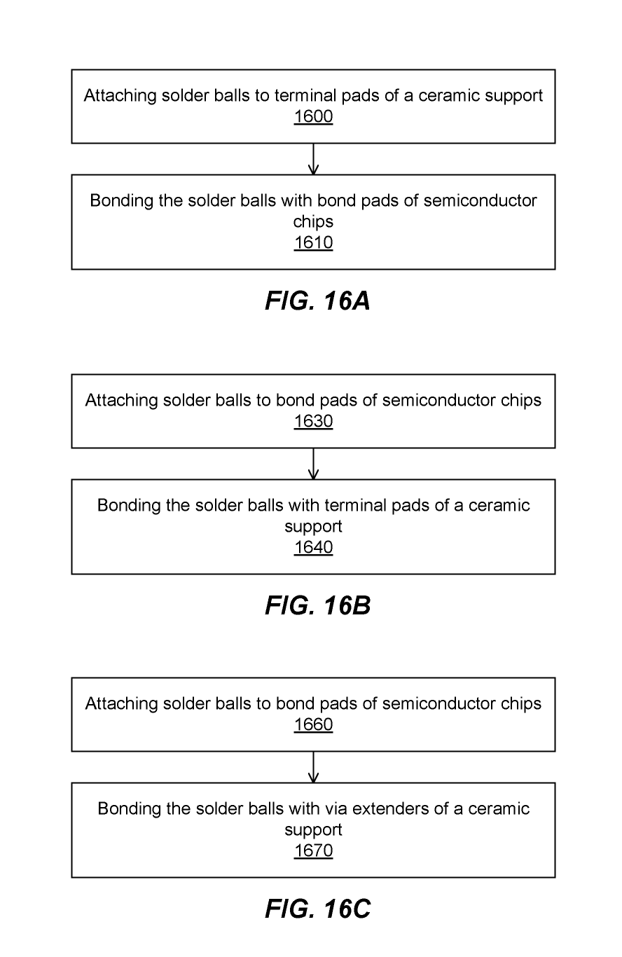

FIGS. 16A-16C illustrate flowcharts for bonding ceramic boards with semiconductor chips according to some embodiments. In FIG. 16A, operation 1600 attaches solder balls to terminal pads of a ceramic support. Operation 1610 bonds the solder balls with bond pads of semiconductor chips.

In FIG. 16B, operation 1630 attaches solder balls to bond pads of semiconductor chips. Operation 1640 bonds the solder balls with terminal pads of a ceramic support.

In FIG. 16C, operation 1660 attaches solder balls to bond pads of semiconductor chips. Operation 1670 bonds the solder balls with via extenders of a ceramic support

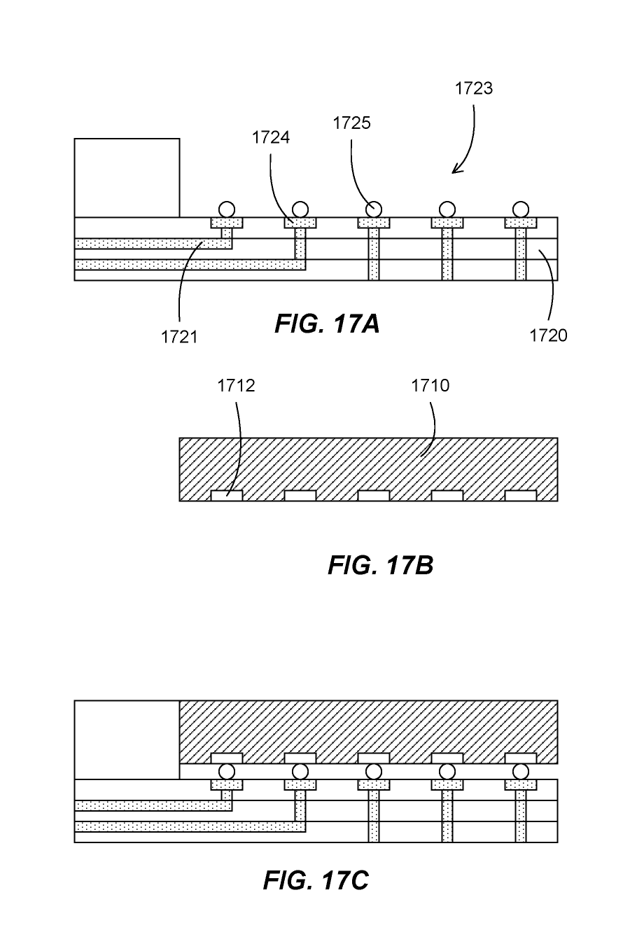

FIGS. 17A-17B illustrate configurations for bonding ceramic boards with semiconductor chips according to some embodiments. In FIG. 17A, the ceramic board 1720 can have pockets 1723 for accommodating semiconductor chips 1710. The ceramic board can also have terminal pads 1724 disposed within the pockets, which can be bonded to the bond pads 1712 of the semiconductor chips 1710 through solder balls 1711.

In FIG. 17B, the semiconductor chips 1710 can have bond pads 1712, which can be configured to be mated with the terminal pads 1724 of the ceramic board through solder balls 1725. In FIG. 17C, the semiconductor chips 1710 can be placed in the pockets 1723 of the ceramic board 1720, with the bond pads matching the terminal pads so bonding can occur.

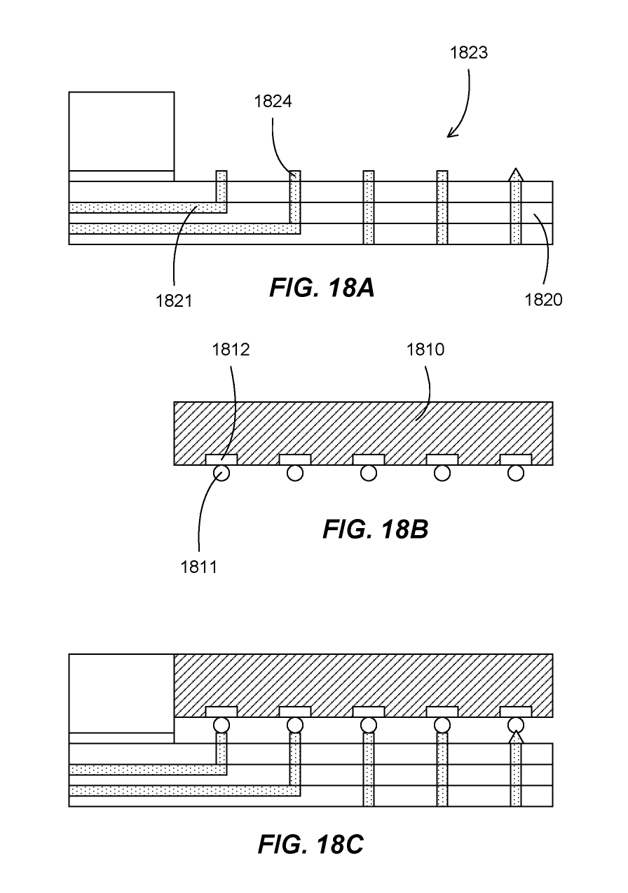

FIGS. 18A-18B illustrate configurations for bonding ceramic boards with semiconductor chips according to some embodiments. In FIG. 18A, the ceramic board 1820 can have pockets 1823 for accommodating semiconductor chips 1810. The ceramic board can also have via extenders 1824 disposed within the pockets, which can be bonded to the bond pads 1812 of the semiconductor chips 1810 through solder balls 1811. In some embodiments, the via extenders can have sharp tips to assist in contacting the bond pads.

In FIG. 18B, the semiconductor chips 1810 can have bond pads 1812, which can be configured to be mated with the via extenders 1824 of the ceramic board through solder balls 1825. In FIG. 18C, the semiconductor chips 1810 can be placed in the pockets 1823 of the ceramic board 1820, with the bond pads matching the via extenders so bonding can occur.

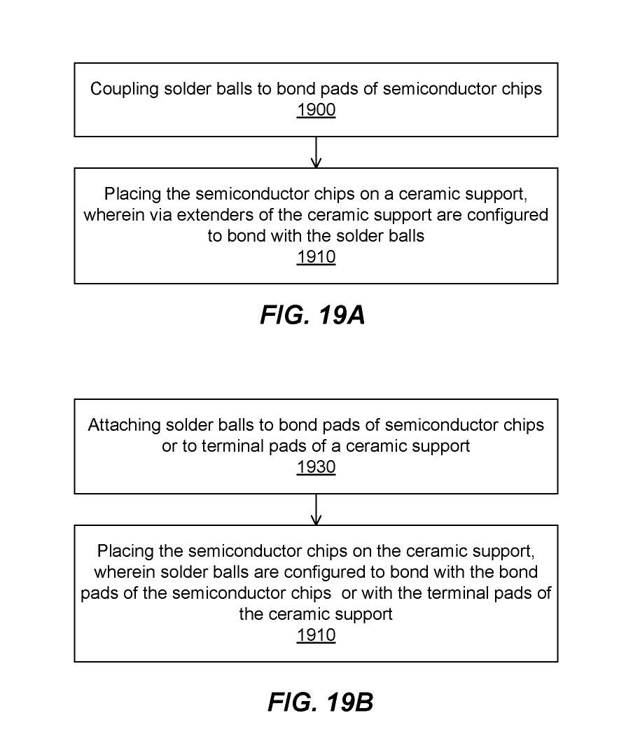

FIGS. 19A-19B illustrate flowcharts for bonding ceramic boards with semiconductor chips according to some embodiments. In FIG. 19A, operation 1900 couples solder balls to bond pads of semiconductor chips. Operation 1910 places the semiconductor chips on a ceramic support, wherein via extenders of the ceramic support are configured to bond with the solder balls.

In FIG. 19B, operation 1930 attaches solder balls to bond pads of semiconductor chips or to terminal pads of a ceramic support. Operation 1940 places the semiconductor chips on the ceramic support, wherein solder balls are configured to bond with the bond pads of the semiconductor chips or with the terminal pads of the ceramic support.

In some embodiments, multiple semiconductor chips can be used to form chip packages. The redistribution layer or the ceramic board can include connecting lines or passive components between the multiple semiconductor chips. The multi-chip packages can reduce the terminal pads, for example, by eliminating contacts that are common between the multiple chips, or there is no need for external connection with the internal connections between the multiple chips. The multi-chip packages can simplify the board connection, using one package instead of multiple packages.

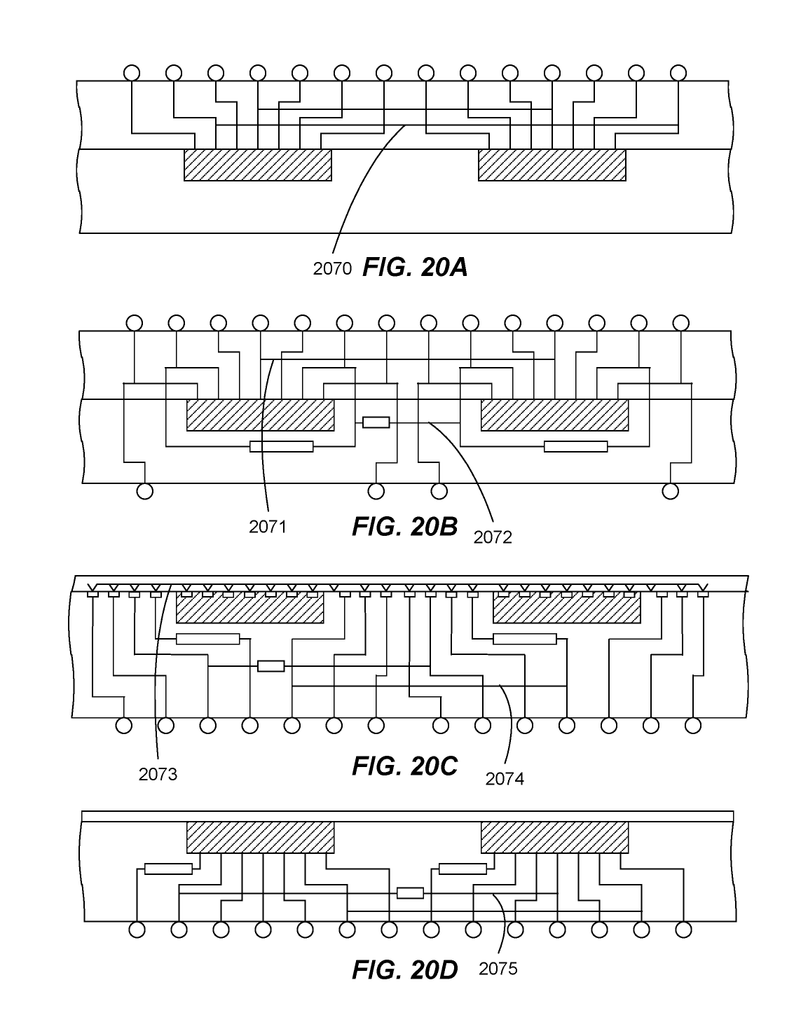

FIGS. 20A-20D illustrate configurations of multi-chip packages according to some embodiments. In FIG. 20A, the redistribution layer can include cross connection lines 2070 between the multiple semiconductor chips. In FIG. 20B, the redistribution layer can include cross connection lines 2071 between the multiple semiconductor chips. The ceramic board can include passive components and cross connection lines 2072 between the multiple semiconductor chips. In FIG. 20C, the interconnect sheet can include cross connection lines 2073 between the multiple semiconductor chips. The ceramic board can include passive components and cross connection lines 2074 between the multiple semiconductor chips. In FIG. 20D, the ceramic board can include passive components and cross connection lines 2075 between the multiple semiconductor chips.

What is claimed is

1. A method comprising
forming a ceramic board,
wherein forming the ceramic board comprises
stacking first sheets of a sinterable ceramic material, wherein the stack of the first sheets comprises recesses configured to accept semiconductor chips, wherein the sinterable ceramic material comprises a thermal expansion coefficient similar to that of silicon,
placing second sheets at the top and bottom of the stack of the first sheets, wherein the second sheets comprise an unsinterable ceramic material, sintering the stack of first and second sheets, removing the second sheets;
placing the semiconductor chips in the recesses;
forming a redistribution layer on the ceramic board covering the semiconductor chips, wherein the redistribution layer comprises interconnects connecting bond pads of the semiconductors to external terminal pads on the redistribution layer, wherein a first separation between the terminal pads is larger than a second separation between the bond pads.

2. A method as in claim 1
wherein the thermal expansion coefficient of the sinterable ceramic material is less than 20% different from the thermal expansion coefficient of silicon.

3. A method as in claim 1 further comprising
forming solder balls on the terminal pads.

4. A method as in claim 1 further comprising
dicing the ceramic board to form individual packages, wherein each individual package comprises one semiconductor chip.

5. A method as in claim 1
wherein the interconnects cross connecting multiple semiconductor chips with the external terminal pads,
wherein the method further comprises dicing the ceramic board to form individual packages, wherein each individual package comprises the multiple semiconductor chips.

6. A method as in claim 1 further comprising
coating the recesses with an adhesive layer before placing the semiconductor chips.

7. A method as in claim 1 further comprising
coating the recesses with a filler layer before placing the semiconductor chips.

8. A method comprising
forming a ceramic board,
wherein forming the ceramic board comprises
stacking first sheets of a sinterable ceramic material, wherein the sinterable ceramic material comprises a thermal expansion coefficient similar to that of silicon,
placing second sheets at the top and bottom of the stack of the first sheets, wherein the second sheets comprise an unsinterable ceramic material,
wherein the stack of the first and second sheets comprises recesses configured to accept semiconductor chips, wherein the stack of the first and second sheets comprises terminal pads,
wherein a first separation between the terminal pads is larger than a second separation between bond pads of the semiconductor chips, wherein the stack of the first and second sheets comprises interconnect lines coupling to the terminal pads for redistributing the bond pads,
sintering the stack of first and second sheets,
removing the second sheets;
placing the semiconductor chips in the recesses;
connecting the bond pads to the interconnect lines.

9. A method as in claim 8
wherein connecting the bond pads to the interconnect lines comprises cross connecting the bond pads of multiple semiconductor chips with the interconnect lines,
wherein the method further comprises dicing the ceramic board to form individual packages, wherein each individual package comprises the multiple semiconductor chips.

10. A method as in claim 8
wherein the bond pads are connected to the interconnect lines in a redistribution layer,
wherein the redistribution layer further comprises second terminal pads,
wherein the redistribution layer comprises interconnects connecting the bond pads to the second terminal pads.

11. A method as in claim 1
wherein forming the ceramic board further comprises
embedding at least a passive component in the stack of the first and second sheets before sintering the stack of first and second sheets.

12. A method as in claim 8
wherein connecting the bond pads to the interconnect lines comprises multiple interconnect lines embedded in one or more layers of dielectric.

13. A method as in claim 8
wherein connecting the bond pads to the interconnect lines comprises multiple wires connected to the bond pads in a wire bonding process.

14. A method as in claim 8
wherein connecting the bond pads to the interconnect lines comprises an interconnect sheet having conductive lines with pad endpoints, wherein the pad endpoints are connected to the bond pads by a laser bonding process.

15. A method as in claim 8
wherein connecting the bond pads to the interconnect lines comprises connecting the bond pads to pads in the ceramic board, wherein the pads are coupled to the interconnect lines.

16. A method as in claim 8
wherein the terminal pads comprise via extenders protruded from the ceramic board or via pads embedded in a surface of the ceramic board.

17. A method comprising
forming a ceramic board,
wherein forming the ceramic board comprises
stacking first sheets of a sinterable ceramic material,
placing second sheets at the top and bottom of the stack of the first sheets, wherein the second sheets comprise an unsinterable ceramic material,
wherein the stack of the first and second sheets comprises recesses configured to accept semiconductor chips,
wherein the stack of the first and second sheets comprises first terminal pads and second terminal pads, wherein a first separation between the first terminal pads is larger than a second separation between bond pads of the semiconductor chips,
wherein the stack of the first and second sheets comprises interconnect lines coupling to the first terminal pads to the second terminal pads,
sintering the stack of first and second sheets,
removing the second sheets;
placing the semiconductor chips in the recesses,
wherein the bond pads are configured to face the second terminal pads for bonding with the second terminal pads;
forming an encapsulate layer on the ceramic board covering the semiconductor chips.

18. A method as in claim 17
wherein connecting the bond pads to the interconnect lines comprises cross connecting the bond pads of multiple semiconductor chips with the interconnect lines,
wherein the method further comprises dicing the ceramic board to form individual packages, wherein each individual package comprises the multiple semiconductor chips.

19. A method as in claim 17
wherein the encapsulate layer comprises interconnects for connecting the interconnect lines.

20. A method as in claim 17 further comprises
embedding at least a passive component in the stack of the first and second sheets before sintering the stack of first and second sheets.
